(19) United States
(12) Patent Application Publication
(10) Pub. No.: US 2025/0299709 A1
(43) Pub. Date: Sep. 25, 2025

(54) SEMICONDUCTOR MEMORY

(71) Applicant: Kioxia Corporation, Tokyo (JP)

(72) Inventor: Atsushi KAWASUMI, Fujisawa Kanagawa (JP)

(73) Assignee: Kioxia Corporation, Tokyo (JP)

(21) Appl. No.: 19/082,901

(22) Filed: Mar. 18, 2025

(30) Foreign Application Priority Data
Mar. 21, 2024 (JP) 2024-045290

(51) Int. Cl. G11C 5/06; G11C 11/4091

(52) U.S. Cl. CPC G11C 5/063; G11C 11/4091

(57) ABSTRACT

A semiconductor memory includes memory cell groups storing first data; pairs of first wiring lines transmitting second data including bits; second wiring lines transmitting a signal corresponding to a product of one bit of the first data and a corresponding bit of the second data; sense amplifiers sensing the signal corresponding to the product transmitted from the second wiring lines; a third wiring line transmitting a signal corresponding to a value adding the products; and switches disposed between the second wiring lines and the third wiring line, each being in an off state in order to disconnect the second wiring lines and the third wiring line until data read to the second wiring lines from the memory cell groups and sensed by the sense amplifiers is rewritten to the memory cell groups, and turned on to connect the second wiring lines and the third wiring line.

### CROSS REFERENCE TO RELATED APPLICATIONS

This application is based upon and claims the benefit of priority from the prior Japanese Patent Application No. 2024-045290, filed on Mar. 21, 2024, the entire contents of which are incorporated herein by reference.

### FIELD

One or more embodiments of the present invention relate to a semiconductor memory.

### BACKGROUND

Machine learning is spreading widely in various fields. Machine learning requires performing a considerable number of multiply-accumulate operations at a high speed to repeatedly update weight coefficients. As a method of performing a great number of multiply-accumulate operations, CIM (Computer In Memory) is attracting attention. In a CIM, multi-dimensional training data sets are inputted/outputted using bit lines and word lines of existing semiconductor memories. As the quality of machine leaning is improving, the number of dimensions of data increases, and therefore the circuit size of the CIM is required to increase. The limit to the access speed and the number of accesses relating to the semiconductor memory used for the CIM affects the reliability of the multiply-accumulate operations. As the configuration size of the CIM increases, the power consumption may also increase.

### BRIEF DESCRIPTION OF THE DRAWINGS

FIG. 1A shows inner product values of two one-dimensional data sets, each having two values.

FIG. 1B shows inner product values of two one-dimensional data sets each having four values.

FIG. 2 shows a distribution curve w1 of the calculation result of 256-dimensional data sets in the case of FIG. 1A and a distribution curve w2 of the calculation result of 36-dimensional data sets in the case of FIG. 1B.

FIGS. 3A to 3D illustrate a multiplication method of a semiconductor memory according to an embodiment.

FIG. 4 illustrates an example in which two memory cell groups shown in FIGS. 3B and 3D are connected to a single bit line.

FIG. 5A is a block diagram of a configuration for multiplying first data and second data.

FIG. 5B is a block diagram of a configuration for a multiply-accumulate operation performed on the first data and the second data.

FIG. 6A is a block diagram showing a modification of FIG. 5A.

FIG. 6B is a block diagram showing a modification of FIG. 5B.

FIG. 7 is a circuit diagram illustrating an internal configuration of a sense amplifier according to the embodiment.

FIG. 8 is a voltage waveform diagram made by simulation, showing changes in the voltage levels of local bit lines and a global bit line pair.

FIG. 9 is a diagram showing inner product values obtained as a result of an inner product calculation of the first data and the second data used in the simulation.

### DETAILED DESCRIPTION

According to an embodiment of the present invention, a semiconductor memory is proposed, the semiconductor memory including: a plurality of memory cell groups each configured to store one bit of first data including a plurality of bits; a plurality of pairs of first wiring lines configured to transmit second data including a plurality of bits; a plurality of second wiring lines each configured to transmit a signal corresponding to a product of one of the bits of the first data and a corresponding bit of the second data; a plurality of sense amplifiers each configured to sense the signal corresponding to the product transmitted from each of the second wiring lines; a third wiring line configured to transmit a signal corresponding to a value obtained by adding a plurality of the products; and a plurality of switches each disposed between one of the second wiring lines and the third wiring line, each being in an off state in order to disconnect the one of the second wiring lines and the third wiring line until data read to the one of the second wiring lines from a corresponding one of the memory cell groups and sensed by a corresponding one of the sense amplifiers is rewritten to the corresponding one of the memory cell groups, and then turned on to connect the corresponding one of the second wiring lines and the third wiring line.

Embodiments of a semiconductor memory will be described below with reference to the accompanying drawings. Although main parts of the semiconductor memory will be mainly described below, the semiconductor memory may include an element or a function that is not illustrated or described. The following descriptions do not exclude any element or function that is not illustrated or described.

A CIM performs multiply-accumulate operations of multi-dimensional data sets. A multiply-accumulate operation of multi-dimensional data sets is equivalent to a calculation of inner product values of vectors each having a plurality of elements. Therefore, a multiply-accumulate operation may be called “inner product calculation” herein.

When an inner product is calculated by using a CIM, the result of the calculation may be detected as a current flowing through a bit line or a voltage of the bit line, for example. If the power consumption of the CIM needs to be decreased, it is preferable that the average value of the current flowing thought the bit line or the voltage of the bit line be reduced as much as possible.

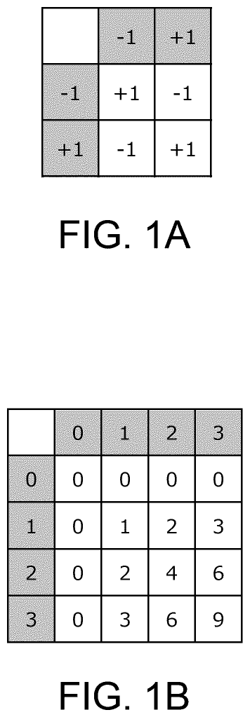

FIG. 1A shows inner product values of two one-dimensional (1 bit) data sets, of which each dimension (bit) may have one of two values, −1 and +1. In this case, the inner product value is either +1 or −1. Therefore, the mean value μ of the inner product values is 0 and the variance σ² is 1.0. In a case of two 256-dimensional data sets in which each dimension may have either −1 or +1 like the case of FIG. 1A, the mean value μ of the inner product values is 0, and the variance σ² is 256.

FIG. 1B shows inner product values of two one-dimensional data sets, of which each dimension may have one of four values, 0, 1, 2, and 3. In this case, the inner product value is one of 0, 1, 2, 3, 4, 6, and 9. Therefore, the mean value μ of the inner product value is 2.25, and the variance σ² is 7.1875. In a case of two 36-dimensional data sets in which each dimension may have one of the four values 0, 1, 2, and 3 like the case of FIG. 1B, the mean value μ of the inner product value is 81 and the variance σ² is 258. The reason why the dimension of the data set is 36 is to set the variance σ² (258) of the data sets, of which each dimension has four values like the case shown in FIG. 1B, to be about the same as the variance σ² (256) of the data sets, of which each dimension has two values like the case shown in FIG. 1A.

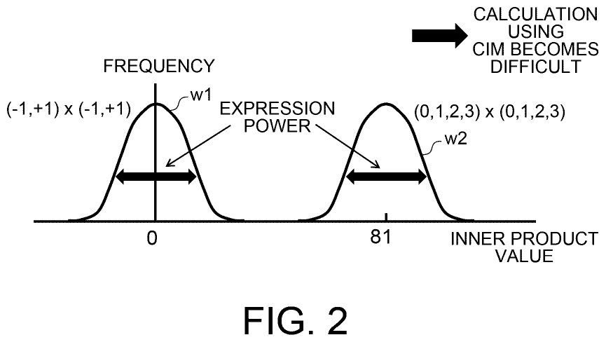

FIG. 2 shows a distribution curve w1 of the calculation result of the 256-dimensional data sets in the case of FIG. 1A and a distribution curve w2 of the calculation result of the 36-dimensional data sets in the case of FIG. 1B. The horizontal axis of FIG. 2 indicates the inner product value, and the vertical axis indicates the frequency. The variance σ² of the distribution curve w1 is 256, and the variance σ² of the distribution curve w2 is 258.75. The widths of the distribution curves w1 and w2 are substantially the same. The width of each curve represents the discriminability or expressive power of the inner product values. The expressive power is substantially the same for the distribution curves w1 and w2. However, the inner product values of the distribution curve w2 are larger than those of the distribution curve w1. The larger inner product values indicate that the current flowing through the bit line or the voltage of the bit line is higher. If the inner product values are larger, a higher current or a higher voltage should be detected for the bit line. This increases the power consummation and therefore makes it difficult to perform calculations using a CIM.

As can be understood from FIGS. 1A, 1B, and 2, if the data set to be subjected to the inner product calculation includes a positive element and a negative element, the mean value of the inner product values may be reduced, and the inner product values may be detected at a low power consumption. Therefore, this case is more suitable for the calculation using a CIM.

Generally, a nonvolatile memory such as a NAND flash memory is used for a CIM. However, it is not easy for a nonvolatile memory to store negative values. Therefore, if inner product values of data sets are calculated using a nonvolatile memory, inner product values become large. Furthermore, if a nonvolatile memory is used in a CIM, as the number of dimensions of data increases, the inner product values increase. Therefore, the number of dimensions of data cannot be increased very much.

In a nonvolatile memory, the threshold value of each memory cell transistor needs to be controlled depending on the element of data. Therefore, as the size of each memory cell transistor decreases, or when each memory cell transistor is driven with a low voltage, the threshold value may not be stably controlled.

In a semiconductor memory according to an embodiment, a dynamic random access memory (DRAM) is used for a CIM calculation. As will be described later, a DRAM may easily perform calculation of negative numbers with a simple expression. Therefore, if inner product values of data sets are calculated using a DRAM, the mean value μ of the inner product values may be set to be 0. Furthermore, even if the number of dimensions of each data set increases, the mean value μ of the inner product values may be maintained to be 0. Therefore, there is no problem if the number of dimensions of each data set increases.

Each memory cell of a DRAM has a capacitor. Since each element of a data set may be stored in the capacitor, the elements of the data set may be more simply and more reliably stored in a DRAM than a nonvolatile memory that controls the threshold value. Therefore, the number of dimensions of data sets may be more easily increased in a DRAM than in a nonvolatile memory.

A NAND flash memory, which is a typical nonvolatile memory, has employed a three-dimensional structure to increase the capacity. However, since the size of memory cell transistors is being decreased, the number of possible writing operations is being decreased. However, since a DRAM has a simple structure to store data in capacitor, there is no limitation in the number of write operations. Therefore, if a DRAM is used, the inner product calculation may be reliably performed, and the cost may be reduced.

A DRAM may read data at a higher speed and with a lower power consumption than a NAND flash memory.

If a static random access memory (SRAM) is used instead of a DRAM, the memory cell structure may become more complicated. Furthermore, an SRAM is inferior to a DRAM with respect to the level of integration and the degree of power consumption.

DRAMs have some defects. Since DRAMs perform destructive read operation, when data is read from a DRAM, the read data should be rewritten (restored). However, if a CIM calculation is performed using the DRAM, the data read out from the DRAM is used for multiplication and multiply-accumulate operation performed on the bit line, and the data on the bit line is changed. Therefore, the DRAM used to perform the CIM calculation needs to have a configuration to rewrite the data to the DRAM before the data changes depending on the result of the calculation.

Since a DRAM is a volatile memory, every time the semiconductor memory is turned on or reset, a load operation needs to be performed to store data in the DRAM again. However, since the data load operation may be performed during an initialization operation, it does not necessarily decrease the calculation efficiency of the CIM.

As described above, the memory capacity of a NAND flash memory having a three-dimensional structure has been increasing. Although a DRAM does not have a memory capacity equivalent to that of a NAND flash memory, it is possible for a DRAM to calculate inner product values of high-dimensional data sets by, for example, dividing the high-dimensional data sets.

Although the speed of a read operation performed by a DRAM may be slower than that performed by an SRAM, it is possible for a DRAM to calculate inner product values speedily by performing, for example, parallel computing.

The semiconductor memory according to the embodiment has overcome the defects of DRAMs described above, and perform CIM calculation using a DRAM.

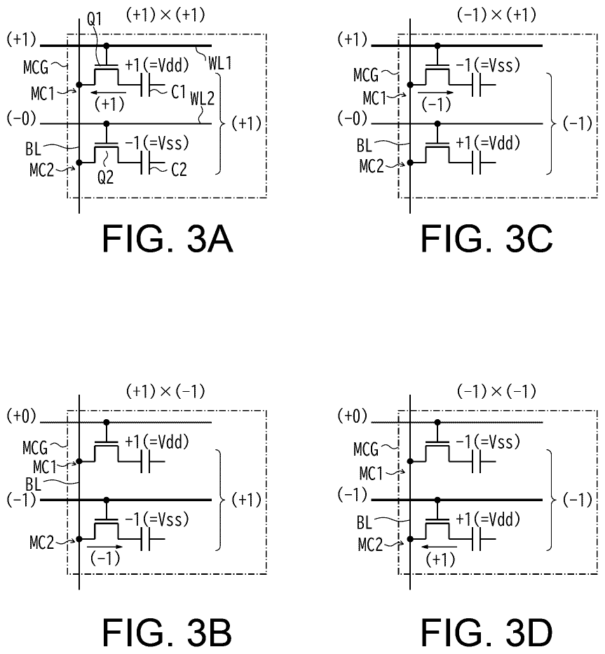

FIG. 3 shows a multiplication method of a semiconductor memory according to the embodiment, which performs multiplication of a first data set and a second data set both including a negative number, using a DRAM. As a minimum unit, the semiconductor memory according to the embodiment includes a memory cell group MCG with two memory cells MC1 and MC2, two word lines WL1 and WL2, and one bit line BL. The first data set supplied via the bit line BL has a plurality of bits, each of which has a value of (+1) or (−1), for example. Similarly, the second data set supplied via the word lines WL1 and WL2 has a plurality of bits, each of which has a value of (+1) or (−1), for example. The two memory cells MC1 and MC2 included in the memory cell group MCG store complementary data. Specifically, the capacitor of one of the memory cells MC1 and MC2 is charged to have a potential Vdd, and the capacitor of the other is caused to discharge to have a potential Vss. For example, if the first data is (+1), the capacitor of one of the memory cells included in the memory cell group MCG is charged, and the capacitor of the other is caused to discharge. If the first data set is (−1), the capacitor of the one of the memory cells included in the memory cell group MCG is caused to discharge and the capacitor of the other is charged.

The two word lines WL1, WL2 are connected to the two memory cells MC1 and MC2 included in the memory cell group MCG. The two word lines WL1 and WL2 may be called “word line pair” herein. For example, if the second data is (+1), one of the word lines that is connected to the memory cell MC1 of the memory cell group MCG is driven, and the other of the word lines that is connected to the memory cell MC2 is not driven. If the second data is (−1), the other of the word lines that is connected to the memory cell MC2 of the memory cell group MCG is driven, and the one of the word lines that is connected to the memory cell MC1 is not driven. A signal having a voltage level sufficient to turn on the corresponding memory cell transistor is supplied to the driven word line, and the word line that is not driven is set at a voltage level for turning off the corresponding memory cell transistor (for example, the ground level).

FIGS. 3A to 3D show an example in which one-bit data of the first data set is multiplied with one-bit data of the second data set. In FIGS. 3A to 3D, the second data supplied via the word line WL1 connected to the memory cell MC1 when the word line WL1 is driven is indicated by (+1), and the second data supplied via the word line WL2 that is not driven is indicated by (−0). The second data supplied via the word line WL2 connected to the memory cell MC2 when the word line WL2 is driven is indicated by (−1), and the second data supplied via the word line WL1 that is not driven is indicated by (+0). The word line that is driven is shown as a broad line and the word line that is not driven is shown as a narrow line in each drawing.

FIG. 3A shows the direction of a current flowing through the memory cell transistors Q1 and Q2 if the one-bit data of the first data set and the one-bit data of the second data set are both (+1). In this case, the result of the multiplication is (+1), and a current flows from the memory cell MC1 to the bit line BL. No current flows between the memory cell MC2 and the bit line BL.

FIG. 3B shows the direction of a current flowing through the memory cell transistors Q1 and Q2 if the one-bit data of the first data set is (+1) and the corresponding one-bit data of the second data set is (−1). In this case, the multiplication result is (−1), and a current flows from the bit line BL to the memory cell MC2. No current flows between the memory cell MC1 and the bit line BL.

FIG. 3C shows the direction of a current flowing through the memory cell transistors Q1 and Q2 if the one-bit data of the first data set is (−1) and the one-bit data of the second data set is (+1). In this case, the multiplication result is (−1), and a current flows from the bit line BL to the memory cell MC1. No current flows between memory cell MC2 and the bit line BL.

FIG. 3D shows the direction of a current flowing through the memory cell transistors Q1 and Q2 if the one-bit data of the first data set and the one-bit data of the second data set are both (−1). In this case, the multiplication result is (+1), and a current flows from the memory cell MC2 to the bit line BL. No current flows between the memory cell MC1 and the bit line BL.

Thus, as can be understood from FIGS. 3A to 3D, the capacitor of one of the two memory cells MC1 and MC2 included in the memory cell group MCG is charged depending on whether the one-bit data of the first data set has a positive value or a negative value, and the capacitor of the other memory cell is caused to discharge. As a result, a positive value or a negative value can be stored in the memory cell group MCG.

If the one-bit data of the second data set is (+1), the word line WL1 of the two word lines connected to the two memory cells MC1 and MC2 is driven, and if the one-bit data is (−1), the word line WL2 is driven. As a result, the multiplication of the one-bit data of the first data set having a value of (+1) or (−1) and the one-bit data of the second data set having the value of (+1) or (−1) can be performed using the memory cell group MCG shown in FIGS. 3A to 3D.

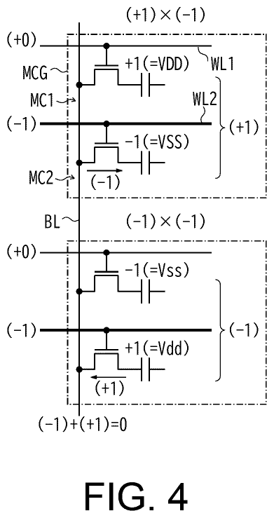

FIG. 4 illustrates an example in which two memory cell groups MCG shown in FIGS. 3B and 3D are connected to a single bit line BL. Different the word line pairs WL1 and WL2 are connected to the two memory cell groups MCG. Each memory cell group MCG performs multiplication of first data stored in the memory cell group MCG and the second data supplied via the word line pair WL1 and WL2. Depending on the value of the product (result of the multiplication) calculated by each memory cell group MCG, the current flowing through the bit line BL or the voltage of the bit line BL changes.

In the example shown in FIG. 4, one of the memory cell groups MCG outputs a value (−1) of the product of the first data (+1) and the second data (−1) to the bit line BL, and the other outputs a value of the product of the first data (−1) and the second data (+1) to the bit line BL. As the result of the multiplication of the first data and the second data, in the one of the memory cell groups MCG, a current flows from the bit line BL to the memory cell MC2, and in the other of the memory cell groups MCG, a current flows from the memory cell MC2 to the bit line BL. Therefore, since the two product values are added on the bit line BL and the result (−1)+(+1)=0 is obtained, no current flows through the bit line BL, and no change in voltage occurs on the bit line BL.

As described above, a destructive read operation is performed in a DRAM and therefore in order to maintain data in the DRAM, the read data should be rewritten. However, in the case of FIG. 4, the data read from one memory cell of each memory cell group MCG is changed on the bit line BL. Therefore, the same data cannot be rewritten to the memory cell.

As will be described below, the semiconductor memory including the memory cell groups MCG shown in FIGS. 3A to 3D of a DRAM according to the embodiment performs a multiply-accumulate operation after the data read from a memory cell is rewritten to the memory cell.

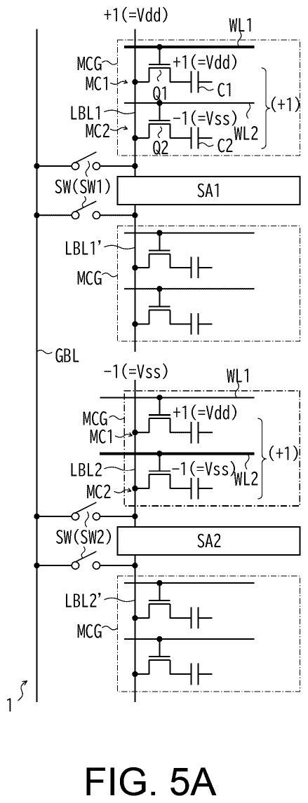

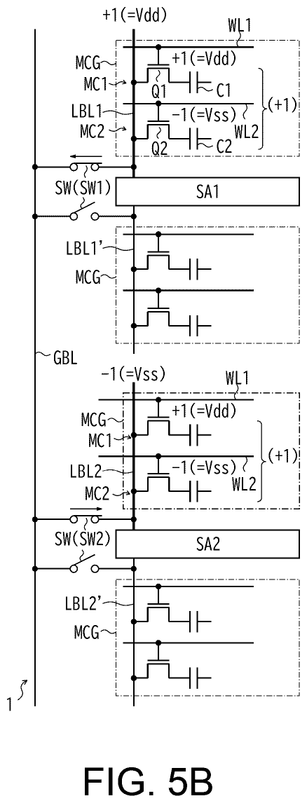

FIGS. 5A and 5B are block diagrams of a semiconductor memory 1 according to the embodiment. FIG. 5A shows a configuration for a multiplication of first data set including a plurality of bits and second data set including a plurality of bits. FIG. 5B shows a configuration for a multiply-accumulate operation for adding the values obtained by multiplications. Each of the bits of the first data set and the second data set may have a positive value or a negative value.

As shown in FIGS. 5A and 5B, the semiconductor memory 1 according to the embodiment includes a global bit line (third wiring line) GBL, pairs of local bit lines (pairs of second wiring lines) LBL1 and LBL1′ and LBL2 and LBL2′, a plurality of memory cell groups MCG each connected to the local bit line LBL1, LBL1′ LBL2, or LBL2′, sense amplifiers SA1 and SA2, a plurality of switches SW, and a plurality of word line pairs (pairs of first wiring lines) WL1 and WL2 each connected to one of the memory cell groups MCG. Herein a pair of local bit lines may be called a local bit line pair.

The semiconductor memory 1 according to the embodiment may include an element other than those shown in FIGS. 5A and 5B. For example, the semiconductor memory 1 according to the embodiment includes a row decoder connected to the word line pairs WL1 and WL2 and a column decoder connected to the global bit line GBL and the local bit lines LBL1 and LBL2, but the row decoder and the column decoder are not shown in the drawings.

The word line WL1 of each word line pair WL1 and WL2 is driven when the corresponding first data has a positive value, and the word line WL2 is driven when the corresponding first data has a negative value. A voltage is supplied to the word line to be driven, the voltage being sufficient to turn on a memory cell transistor Q1 or Q2 connected to the word line to be driven.

One local bit line of the pair of local bit lines LBL1 and LBL1′ is connected to the memory cell group MCG for storing the first data. The other local bit line is used as a reference potential data line having a potential of, for example, ½ Vdd. The same can be said for the pair of local bit lines LBL2 and LBL2′.

A switch SW is disposed between the global bit line GBL and each local bit line of the pairs of local bit lines LBL1, LBL1′, LBL2, and LBL2′.

Each of the switches SW is in the off state, by which the connection between the corresponding local bit line LBL and the global bit line GBL is disconnected, until data read from any one of the memory cell groups MCG to the corresponding local bit line LBL and sensed by a corresponding sense amplifier SA1 or SA2 is rewritten to the memory cell group MCG. The switch SW is then turned on to connect the corresponding local bit line LBL and the global bit line GBL.

The switches SW include first switches SW1 disposed between the local bit lines LBL1 and LBL1′ and the global bit line GBL, and second switches SW2 disposed between the local bit lines LBL2 and LBL2′ and the global bit line GBL.

The first switches SW1 disconnect the global bit line GBL from the local bit line LBL1 and LBL1′ until the data read from the memory cell group MCG to the local bit line LBL1 or LBL1′ and sensed by the corresponding sense amplifier SA1 is rewritten to the memory cell group MCG, and then re-connect the local bit line LBL1 or LBL1′ and the global bit line GBL.

The second switches SW2 disconnect the global bit line GBL from the local bit lines LBL2 and LBL2′ until the data read from the memory cell group MCG to the local bit line LBL2 or LBL2′ and sensed by the corresponding sense amplifier SA2 is rewritten to the memory cell group MCG, and then re-connect the local bit line LBL2 or LBL2′ and the global bit line GBL.

In FIGS. 5A and 5B, the pairs of local bit lines LBL1, LBL1′ and LBL2, LBL2′ are respectively arranged along the same line like an open bit line method, but the pairs of local bit lines LBL1, LBL1′ and LBL2, LBL2′ may be arbitrarily disposed. For example, like a folded bit line method, the pair of local bit lines LBL1, LBL1′ may be separately disposed in a row direction, and the pair of local bit lines LBL2, LBL2′ may also be separately disposed in a row direction.

During a period of time in which any one of the memory cell groups MCG connected to the same local bit line LBL sends a signal corresponding to a product (multiplication result) to the local bit line LBL, the rest of the memory cell groups MCG do not send to the local bit line LBL a signal corresponding to a product. Thus, it is not possible for two or more memory cell groups MCG connected to the same local bit line LBL to perform multiplications in parallel. They sequentially perform multiplications.

Each memory cell group MCG includes two memory cells MC1 and MC2 for storing one-bit data that is a minimum unit of the first data. Since the first data has a plurality of bits, a configuration equivalent to that of the memory cell group MCG shown in FIG. 5 is needed for each bit of the first data, as will be described later.

Each memory cell in the memory cell groups MCG is a DRAM cell. Each memory cell group MCG includes memory cell transistors Q1 and Q2 and capacitors C1 and C2. The two word lines WL1 and WL2 (word line pair WL1, WL2) are connected to the gates of the two memory cell transistors Q1 and Q2 included in each memory cell group MCG. Depending on whether the second data has a positive or negative value, one of the word line WL1 of the word line pair WL1, WL2 is driven and the other word line WL2 is not driven.

One of the two memory cells MC1 and MC2, the memory cell MC1, included in each memory cell group MCG stores one-bit data of the first data set and the other, the memory cell MC2, stores inversed data of the one-bit data of the first data set. The one-bit data of the first data set has either a positive or negative value. For example, if the first data has a positive value (for example, +1), the capacitor C1 included in the memory cell MC1 is charged, and the capacitor C2 of the memory cell MC2 is caused to discharge. If the first data has a negative value (for example,-1), the capacitor C1 of the memory cell MC1 is caused to discharge and the capacitor C2 of the memory cell MC2 is charged.

If the product of the first data and the second data is a positive value, a current flows from one of the memory cells MC included in the memory cell group MCG to the corresponding local bit line LBL, and if the product is a negative value, a current is drawn to one of the memory cells MC included in the memory cell group MCG from the corresponding local bit line LBL.

When the multiplication of corresponding bits of the first data and the second data is performed in one of the memory cell groups MCG shown in FIG. 5A, a corresponding switch SW is turned off to cause a current to flow through one of the local bit lines LBL1, LBL2 in a direction depending on the positive or negative value of the product of the first data and the second data, and a signal on the local bit line LBL1 or LBL2 sensed by the sense amplifier SA1 or SA2 is rewritten to the one of the memory cell groups MCG.

After the rewriting of data to the one of the memory cell groups MCG is finished and when the word lines WL1 and WL2 are not driven any more, the corresponding switch SW is turned on as shown in FIG. 5B, and a current flows between the global bit line GBL and the corresponding local bit line LBL depending on the value of the product calculated by the one of the memory cell groups MCG. In the example shown in FIG. 5B, the product calculated by the uppermost memory cell group MCG connected to the local bit line LBL1 is (+1), and therefore a current flows from the memory cell group MCG to the global bit line GBL via one of the switches SW1 disposed on this memory cell group MCG side. The other of the switches SW1 is turned off. The product calculated by the second memory cell group MCG from the bottom connected to the local bit line LBL2 is (−1), and therefore a current flows from the global bit line GBL to the memory cell group MCG via one of the switches SW2 on this memory cell group MCG side. The other of the switches SW2 is turned off. As a result, the voltage level of the voltage on the global bit line GBL is (+1)+(−1)=0, which is the same as the value before the multiply-accumulate operation is performed. Since the data read from the respective memory cell groups MCG have been rewritten to the corresponding memory cell groups MCG, the voltage level of the global bit line GBL does not affect the data retained by the memory cell groups MCG. In the state shown in FIG. 5B, the sense amplifiers SA1 and SA2 may be deactivated or disconnected from the local bit lines LBL1 and LBL2.

In FIGS. 5A and 5B, a switch SW is disposed to each memory cell group MCG. However, the arrangement of the switches SW is not necessarily limited to that shown in FIGS. 5A and 5B.

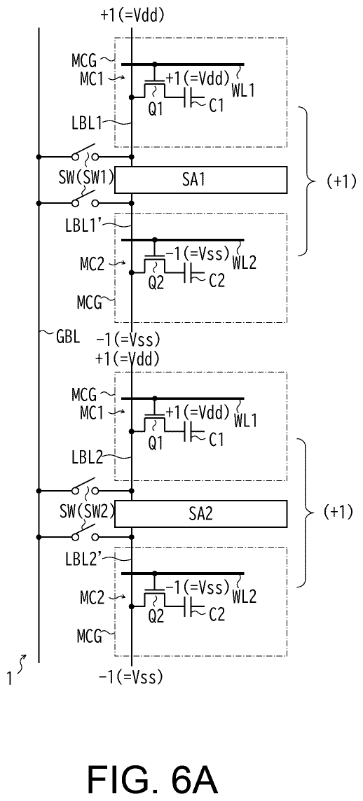

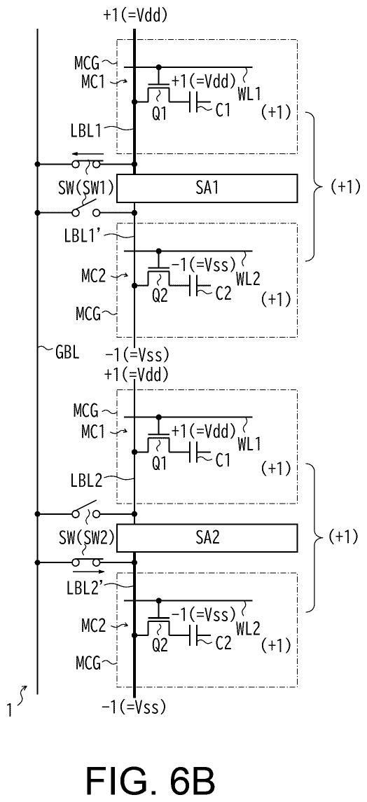

FIGS. 6A and 6B are block diagrams showing a main part of a semiconductor memory 1 according to a modification of the embodiment. FIG. 6A shows the states of the switches SW when the first data is read, and FIG. 6B shows the states of the switches SW during a multiply-accumulate operation after the data is rewritten.

In the semiconductor memory 1 according to the modification shown in FIGS. 6A and 6B, two memory cells MC1 and MC2 included in a memory cell group MCG are connected to a sense amplifier via different local bit lines, and a switch SW is connected to each of the memory cells MC1 and MC2. When the local bit lines LBL1, LBL1′, LBL2, LBL2′ each send signals corresponding to the first data to sense amplifiers SA1 and SA2, the switches SW connected to the two memory cells MC1 and MC2 of each memory cell group MCG having performed multiplication are turned off as shown in FIG. 6A, and the data sensed by the sense amplifiers SA1 and SA2 are rewritten to the memory cell group MCG. After the rewriting and when the word lines WL1 and WL2 are not driven any more, a plurality of multiplication results are added on the global bit line GBL. At this time, as shown in FIG. 6B, one of the switches SW connected to one memory cell of the memory cells MC1 and MC2 included in the memory cell group MCG for which the first data is read is turned on and the other connected to the other memory cell is turned off according to the second data. In this modification, if the second data is (+1), for example, one of the switches SW connected to the memory cell MC1 of the memory cell group MCG is turned on, and the other connected to the memory cell MC2 is turned off. If the second data is (−1), the switch SW connected to the memory cell MC2 of the memory cell group MCG is turned on and the other switch SW connected to the memory cell MC1 is turned off. As a result, the first data having a value of (+1) or (−1) may be multiplied with the second data having a value of (+1) or (−1), and a current corresponding to the product (multiplication result) flows between the local bit line LBL1 or LBL1′ and the global bit line GBL, and also between the local bit line LBL2 or LBL2′ and the global bit line GBL.

In the example shown in FIG. 6B, the current corresponding to the multiplication result (+1) flows from the local bit line LBL1 connected to the memory cell MC1 of the memory cell group MCG to the global bit line GBL via one of the switches SW1 (on the upper side). Furthermore, a current corresponding to the multiplication result (−1) flows from the global bit line GBL to the local bit line LBL2′ connected to the memory cell MC2 of the memory cell group MCG via one of the switches SW2 (on the lower side). As a result, the voltage level of the global bit line GBL becomes the same as that before the multiplication is performed. In the state shown in FIG. 6B, the sense amplifiers SA1 and SA2 may be deactivated or disconnected from the local bit lines LBL1 and LBL2.

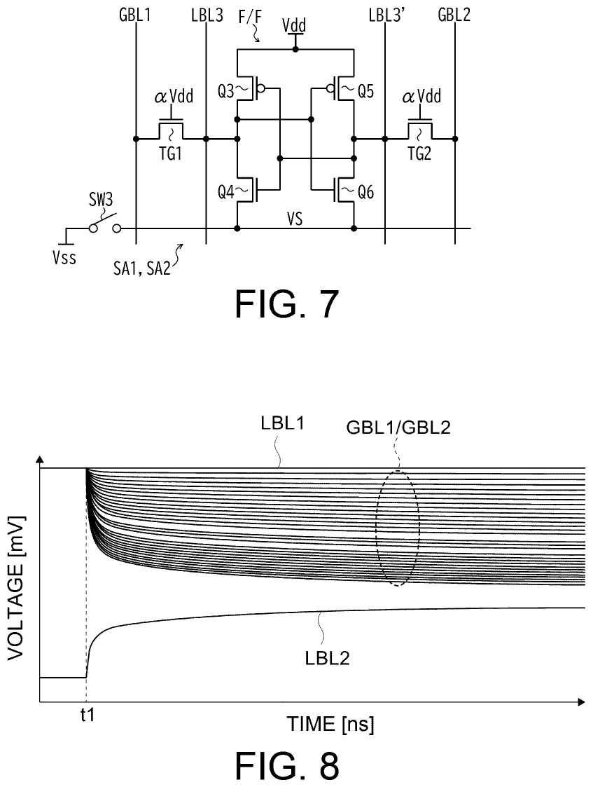

FIG. 7 is a circuit diagram illustrating an internal configuration of the sense amplifiers SA1 and SA2 according to the embodiment. Each of the sense amplifiers SA1 and SA2 includes a flip-flop F/F, a first transfer gate TG1, a second transfer gate TG2, a pair of local bit lines LBL3 and LBL3′, and a pair of global bit lines GBL1 and GBL2. In the following descriptions, the pair of local bit lines LBL3 and LBL3′ may be collectively called “local bit line pair LBL,” and the pair of global bit lines GBL1 and GBL2 may be collectively called “global bit line pair GBL.”

One local bit line LBL3 of the pair of local bit lines LBL3 and LBL3′ shown in FIG. 7 corresponds to the local bit line LBL1 or LBL2 shown in FIG. 5A or FIG. 5B, and the other local bit line LBL3′ corresponds to the local bit line LBL1′ or LBL2′ shown in FIG. 5A or FIG. 5B. The other local bit line LBL3′ transmits a signal obtained by inverting the logic of the signal transmitted by the local bit line LBL3.

Similarly, one global bit line GBL1 of the global bit line pair GBL shown in FIG. 7 corresponds to the global bit line GBL shown in FIG. 5A or FIG. 5B. The other global bit line pair GBL2 of the global bit line pair GBL shown in FIG. 7 is not illustrated in FIGS. 5A and 5B.

The flip-flop F/F is connected to the pair of local bit lines LBL3 and LBL3′ and holds the logics of the signals on the pair of local bit lines LBL3 and LBL3′. The flip-flop F/F includes a PMOS transistor Q3 and an NMOS transistor Q4 that are cascode-connected between a power supply voltage node Vdd and a ground (reference voltage) node VS, and a PMOS transistor Q5 and an NMOS transistor Q6 that are also cascode-connected between the power supply voltage node Vdd and the ground (reference voltage) node VS. The gate of the PMOS transistor Q3 and the gate of the NMOS transistor Q4 are connected to the drain of the PMOS transistor Q5, the drain of the NMOS transistor Q6, and the second transfer gate TG2. The gate of the PMOS transistor Q5 and the gate of the NMOS transistor Q6 are connected to the drain of the PMOS transistor Q3, the drain of the NMOS transistor Q4, and the first transfer gate TG1.

The first transfer gate TG1 switches whether the global bit line GBL1 is connected to the local bit line LBL3 or not. The second transfer gate TG2 switches whether the global bit line GBL2 is connected to the local bit line LBL3′ or not.

A control voltage αVdd obtained by multiplying a power supply voltage level by “α” (0<α<1) is applied to the gate of each of the first transfer gate TG1 and the second transfer gate TG2. By adjusting the value of “α,” the first transfer gate TG1 and the second transfer gate TG2 may be optimally weakly turned on.

The first transfer gate TG1 may be integrated with the switch SW shown in FIG. 5A or FIG. 5B. However, the gate voltage of each of the first transfer gate TG1 and the second transfer gate TG2 may be controlled more easily if the switch SW is separately disposed.

If the sense amplifiers SA1 and SA2 first sense the signals on the local bit lines LBL3 and LBL3′, the signals corresponding to the values of the products calculated by the memory cell groups MCG, and then the switches SW are turned on to perform a multiply-accumulate operation on the global bit line GBL, in some cases the data retained in the flip-flops F/F in the sense amplifiers SA1 and SA2 may change unintentionally due to the influence of the result of the multiply-accumulate operation. In order to solve this problem, in this embodiment, the first transfer gate TG1 and the second transfer gate TG2 of the sense amplifiers SA1 and SA2 are weakly turned on and a switch SW3 is turned off to bring the reference voltage node VS of each flip-flop F/F into an unstable state, for example a floating state. As a result, even if the voltage levels of the global bit line pair GBL1 and GBL2 considerably change due to the influence of the multiply-accumulate operation, the voltage levels of the local bit lines LBL3 and LBL3′ do not abruptly change due to the influence of the voltage level of the global bit line GBL. Therefore, the data retained by the flip-flops F/F is prevented from being unintentionally changed.

The operations of the sense amplifiers SA1 and SA2 will be described below with reference to FIG. 7. The sense amplifiers SA1 and SA2 pre-charge the global bit line pair GBL to be at the power supply voltage level Vdd before each memory cell group MCG performs the multiplication of the first data and the second data. Thereafter, the sense amplifiers SA1 and SA2 set the voltage level of the reference voltage node VS in each flip-flop F/F to be the ground level (for example, 0 V). In this state, each memory cell group MCG performs the multiplication of the first data and the second data, and a current flows from the memory cell group MCG to the local bit line LBL3 or LBL3′, or from the local bit line LBL3 or LBL3′ to the memory cell group MCG depending on the value of the product (multiplication result). As a result, the voltage levels of the local bit lines LBL3 and LBL3′ are set according to the product value. The sense amplifiers SA1 and SA2 sense such voltage levels. After the memory cell group MCG outputs the product value, the sensed voltage levels of the local bit lines LBL3 and LBL3′ are rewritten. The switches SW shown in FIG. 5A have been turned off until this state. Furthermore, the first transfer gate TG1 and the second transfer gate TG2 have been turned off until this state. At this time, for example, one of the local bit lines, the local bit line LBL3, may be set at the power supply voltage level and the other, the local bit line LBL3′, is set at the ground level. In the following descriptions, it is assumed that the local bit line LBL3 is set at the power supply voltage level and the local bit line LBL3′ is set at the ground level.

The switches SW are then turned on as shown in FIG. 5B. The switch SW3 is kept off to make the reference voltage node VS of the flip-flop F/F to be in the unstable (floating) state. The gate voltage αVdd is supplied to the first transfer gate TG1 and the second transfer gate TG2 to weakly turn on the first transfer gate TG1 and the second transfer gate TG2.

As a result, a current flows from the global bit line GBL2 to the local bit line LBL3′ via the second transfer gate TG2, and the current further flows to the reference voltage node VS via the NMOS transistor Q6 of the flip-flop F/F. The voltage level of the reference voltage node VS therefore increases.

The current flowing to the reference voltage node VS is not dependent on the data sensed by the sense amplifiers SA1 and SA2. Since the operating points of the first transfer gate TG1 and the second transfer gate TG2 are in a saturation region, the increase in voltage at the reference voltage node VS, and the current flowing through the first transfer gate TG1 and the second transfer gate TG2 are not dependent on the result of the multiplication of the first data and the second data. The internal configuration of the sense amplifiers SA1 and SA2 shown in FIG. 7 can also be used for the embodiment shown in FIG. 6A and FIG. 6B and the same effect can be obtained in this case.

FIG. 8 is a voltage waveform diagram made by a simulation, showing that the voltage levels of the pair of local bit lines LBL3 and LBL3′ and the global bit line pair GBL change according to the multiplication result of the first data and the second data. In FIG. 8, the horizontal axis indicate the time [ns] and the vertical axis indicates the voltage [mV]. FIG. 8 shows voltage waveforms of the pair of local bit lines LBL3 and LBL3′ and 32 voltage waveforms of the global bit line pair GBL1/GBL2 obtained as the results of the multiplication of the first data and the second data.

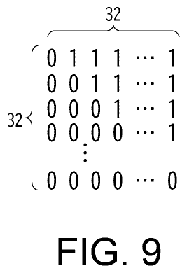

FIG. 9 shows inner product values obtained as a result of a simulation of inner product calculation between first data and second data. As shown in FIG. 9, in the simulation, 32 inner product values represented as 32 bits are calculated by the global bit line pair GBL1/GBL2.

At time t1 in FIG. 8, the switches SW are turned on and the first transfer gate TG1 and the second transfer gate TG2 are weakly turned on. As shown in FIG. 8, when the first transfer gate TG1 and the second transfer gate TG2 are weakly turned on, a current flows from the global bit line GBL to the reference voltage node VS via the second transfer gate TG2 and the NMOS transistor Q6 of the flip-flop F/F, and the voltage levels of the local bit line LBL3′ and the reference voltage node VS increase. The voltage levels of the global bit line GBL1/GBL2 may vary in 32 ways depending on the multiplication results of the first data and the second data.

FIGS. 5A and 5B show the configurations for performing a multiply-accumulate operation with respect to one bit of the first data and one bit of the second data. Since both the first data and the second data have a plurality of bits, the memory cell groups MCG, the pairs of local bit lines LBL1 and LBL1′ and LBL2 and LBL2′, the memory cell groups MCG, the switches SW, and the pairs of word lines WL1 and WL2 shown in FIGS. 5A and 5B are prepared for each of the plurality of bits. Each of the switches SW is connected to the same global bit line GBL. Therefore, the multiply-accumulate operations for the plurality of bits can be performed on the global bit line GBL, and the inner product values of the first data and the second data can be transmitted through the global bit line GBL.

Thus, in the embodiment, a memory cell group MCG including two memory cells MC1 and MC2 may perform calculation of one bit of first data and one bit of second data, each bit of the first data and the second data being either a positive value or a negative value. Since each bit of the first data and the second data is either a positive value or a negative value, the mean value of the inner product values of the first data and the second data each having a plurality of bits may be made zero. Even if the dimensions of the first data and the second data increase, the mean value of the inner product values may be made zero. Therefore, it is possible to perform the inner product calculation (multiply-accumulate operation) of the first data and the second data each having a high dimension with a low power consumption. In the embodiment, each of the memory cells included in the memory cell group MCG is a DRAM cell. Therefore, it is possible to read data from each memory cell at a high speed.

In the embodiment, data may be stored in the capacitor in each DRAM cell. Therefore, it is possible to improve the stability in a write operation as compared to the case of a NAND flash memory in which the threshold value of each memory cell transistor is controlled depending on data.

DRAM cells perform a destructive read operation. Therefore, in the semiconductor memory 1 according to the embodiment, the global bit line GBL is provided in addition to the local bit lines LBL1, LBL1′ and LBL2, LBL2′, and also the switches SW are disposed between the local bit lines and the global bit line GBL. After the product value and the value of the first data are read from the memory cell group MCG and the data sensed by the sense amplifiers SA1, SA2 is rewritten to the memory cell group MCG, the switches SW are turned on to perform a multiply-accumulate operation on the global bit line GBL. Thus, a CIM calculation may be performed using DRAM cells.

The memory cell configuration of a DRAM is simpler than that of a NAND flash memory. There is no limit in the number of writing operations, and data may be read at a high speed and with a low power consumption. Therefore, CIM computing may be performed efficiently with a DRAM.

While certain embodiments have been described, these embodiments have been presented by way of example only, and are not intended to limit the scope of the disclosures. Indeed, the novel methods and systems described herein may be embodied in a variety of other forms; furthermore, various omissions, substitutions and changes in the form of the methods and systems described herein may be made without departing from the spirit of the disclosures. The accompanying claims and their equivalents are intended to cover such forms or modifications as would fall within the scope and spirit of the disclosures.

1. A semiconductor memory comprising:
a plurality of memory cell groups each configured to store one bit of first data including a plurality of bits;
a plurality of pairs of first wiring lines configured to transmit second data including a plurality of bits;
a plurality of second wiring lines each configured to transmit a signal corresponding to a product of one of the bits of the first data and a corresponding bit of the second data;
a plurality of sense amplifiers each configured to sense the signal corresponding to the product transmitted from each of the second wiring lines;
a third wiring line configured to transmit a signal corresponding to a value obtained by adding a plurality of the products; and
a plurality of switches each disposed between one of the second wiring lines and the third wiring line, each being in an off state to disconnect the one of the second wiring lines and the third wiring line until data read to the one of the second wiring lines from a corresponding one of the memory cell groups and sensed by a corresponding one of the sense amplifiers is rewritten to the corresponding one of the memory cell groups, and then turned on to connect the one of the second wiring lines and the third wiring line.

2. The semiconductor memory according to claim 1, wherein each of the bits of the first data and the second data has either a positive value or a negative value.

3. The semiconductor memory according to claim 2, wherein one of the first wiring lines of each of the plurality of pairs of the first wiring lines is driven when a corresponding bit of the first data has the positive value, and the other of the first wiring lines is driven when the corresponding bit of the first data has the negative value.

4. The semiconductor memory according to claim 2, wherein
one of the second wiring lines is connected to one of the memory cell groups configured to store the positive value of the first data, and
another one of the second wiring line is connected to another one of the memory cell groups configured to store the negative value of the first data.

5. The semiconductor memory according to claim 1, wherein during a period of time in which one of the memory cell groups connected to one of the second wiring lines transmits the signal corresponding to the product to the one of the second wiring lines, remaining ones of the memory cell groups do not transmit a signal corresponding to the product to the one of the second wiring lines.

6. The semiconductor memory according to claim 1, wherein each of the memory cell groups include two memory cells for storing one-bit data of the first data and inversed data of the one-bit data.

7. The semiconductor memory according to claim 6, wherein the memory cell is a dynamic random access memory (DRAM) cell.

8. The semiconductor memory according to claim 6, wherein to the two memory cells, a corresponding one of the pairs of the first wiring lines and a corresponding one of the second wiring lines are connected.

9. The semiconductor memory according to claim 8, wherein in accordance with the corresponding bit of the second data, one first wiring line of the corresponding one of the pairs of the first wiring lines is driven, and another first wiring line is not driven.

10. The semiconductor memory according to claim 6, wherein in each of the two memory cells, if the product of one of the bits of the first data and the corresponding bit of the second data has a positive value, a current flows from a corresponding one of the memory cells to a corresponding one of the second wiring lines, and if the product has a negative value, a current is drawn from the corresponding one of the second wiring lines to the corresponding one of the memory cells.

11. The semiconductor memory according to claim 6, wherein a current flows through one of the two memory cells and a corresponding second wiring line in a direction determined by whether the product of the one of the bits of the first data and the corresponding bit of the second data has a positive value or a negative value, and a signal on the corresponding second wiring line sensed by the corresponding one of the sense amplifiers is rewritten to the one of the two memory cells.

12. The semiconductor memory according to claim 6, wherein
one of the switches is disposed for the two memory cells, and
the one of the switches is turned off when the signal corresponding to the product is transmitted to the corresponding one of the sense amplifiers via a corresponding one of the second wiring lines, and is turned on when the signal corresponding to the value obtained by adding the plurality of products is transmitted from the third wiring line.

13. The semiconductor memory according to claim 1, wherein each of the sense amplifier includes:
a flip-flop connected to the second wiring lines and configured to retain a logic of a signal on the second wiring lines;
a first transfer gate configured to switch whether the third wiring line is connected to one of the second wiring lines; and
a second transfer gate configured to switch whether a fourth wiring line that has a logic obtained by inverting a logic of the third wiring line is connected to the flip-flop,
wherein the flip-flop retains a signal corresponding to one of the memory cell groups connected to the second wiring lines, and is controlled so that the retained signal is not changed by a signal on the second wiring lines until the retained signal is transmitted to the third wiring line via a corresponding switch.

14. The semiconductor memory according to claim 13, wherein the flip-flop retains the signal on the second wiring lines with a voltage of a reference voltage node of the flip-flop being set at a predetermined initial voltage, and then the first transfer gate and the second transfer gate are turned on with the voltage of the reference voltage node being set to be unstable, by which a current flows from the third wiring line or the fourth wiring line to the reference voltage node via the first transfer gate or the second transfer gate.

15. The semiconductor memory according to claim 13, wherein the first transfer gate and the second transfer gate are provided separately from the switches.

16. The semiconductor memory according to claim 13, wherein the first transfer gate is one of the switches.

17. The semiconductor memory according to claim 1, wherein
the plurality of the pairs of the first wiring lines are a plurality of word line pairs,
the plurality of the second wiring lines are a plurality of local bit line pairs,
the third wiring line is a global bit line, and
each of the plurality of switches is connected between one of the local bit line pairs and the global bit line.

18. The semiconductor memory according to claim 17, wherein a corresponding one of the local bit line pairs is connected to each of the sense amplifiers.

19. A semiconductor memory comprising:
a plurality of memory cell groups each including two memory cells, each of the two memory cells configured to store one bit of first data including a plurality of bits;
a plurality of pairs of first wiring lines, each pair being connected to the two memory cells of each of the memory cell groups;
a plurality of pairs of second wiring lines each pair connected to the two memory cells of each of the memory cell groups to transmit a signal corresponding to the first data stored in the two memory cells;
a plurality of sense amplifiers each configured to sense the signal corresponding to the first data transmitted through a corresponding pair of the second wiring lines;
a third wiring line;
a plurality of pairs of switches each disposed between one of the pairs of the second wiring lines and the third wiring line and turned off before the first data read from one of the memory cell groups to a corresponding one of the pairs of the second wiring lines and sensed by a corresponding one of the sense amplifiers is rewritten to the one of the memory cell groups, one switch of each of the pairs of switches being turned on depending on a value of a corresponding bit of a plurality of bits of second data and another one switch being kept to be turned off,
the third wiring line configured to transmit a signal corresponding to a value obtained by adding a plurality of products of the first data and the second data, each product being obtained by multiplying one bit of the first data and a corresponding one bit of the second data.

20. The semiconductor memory according to claim 19, wherein each of the sense amplifier includes:
a flip-flop connected to the second wiring lines and configured to retain a logic of a signal on the second wiring lines;
a first transfer gate configured to switch whether the third wiring line is connected to one of the second wiring lines; and
a second transfer gate configured to switch whether a fourth wiring line that has a logic obtained by inverting a logic of the third wiring line is connected to the flip-flop,
wherein the flip-flop retains a signal corresponding to one of the memory cell groups connected to the second wiring lines, and is controlled so that the signal retained is not changed by a signal on the second wiring lines until the signal retained is transmitted to the third wiring line via a corresponding switch.

21. The semiconductor memory according to claim 20, wherein the flip-flop retains the signal on the second wiring lines with a voltage of a reference voltage node of the flip-flop being set at a predetermined initial voltage, and then the first transfer gate and the second transfer gate are turned on with the voltage of the reference voltage node being set to be unstable, by which a current flows from the third wiring line or the fourth wiring line to the reference voltage node via the first transfer gate or the second transfer gate.

22. The semiconductor memory according to claim 20, wherein the first transfer gate and the second transfer gate are provided separately from the switches.

23. The semiconductor memory according to claim 20, wherein the first transfer gate is one of the switches.

24. The semiconductor memory according to claim 19, wherein
the plurality of pairs of the first wiring lines are a plurality of word line pairs,
the plurality of pairs of second wiring lines are a plurality of local bit line pairs,
the third wiring line is a global bit line,
each of the switches is disposed between one of the local bit line pairs and the global bit line, and
each of the local bit line pairs is connected to the corresponding one of the sense amplifiers.
